(19) United States
(12) Patent Application Publication
(10) Pub. No.: US 2024/0394437 A1
(43) Pub. Date: Nov. 28, 2024

(54) DIGITAL AVATAR PLATFORM

(71) Applicant: Schlumberger Technology Corporation, Sugar Land, TX (US)

(72) Inventors: Clare Schoene, Houston, TX (US); Gilles Besancon, Clamart (FR)

(21) Appl. No.: 18/688,537

(22) PCT Filed: Sep. 23, 2021
(86) PCT No.: PCT/US2021/071567

§ 371 Date: Mar. 1, 2024

(51) Int. Cl. G06F 30/20

(52) U.S. Cl. CPC G06F 30/20

(57) ABSTRACT

A platform is provided for implementing a digital representation of a particular industrial asset. The platform is configured to create an avatar corresponding to the particular industrial asset from at least one model and an avatar template, wherein the avatar template refers to or incorporates the at least one model or part thereof, and the avatar is created from the avatar template and refers to or incorporates the avatar template or part thereof: execute a simulation that refers to or incorporates the avatar or part thereof, wherein execution of the simulation uses the at least one model of the avatar template referenced or incorporated by the avatar along with operational data corresponding to the particular industrial asset to generate a digital representation of the particular industrial asset.

### FIELD

The present disclosure relates to a digital avatar platform that provides digital representations of physical devices, systems, or processes.

### BACKGROUND

The Industrial Internet of Things (IIoT) has become more prevalent in industries as digitalization has become one of the top priorities for many organizations. IIOT employ one or more data communication networks, including the Internet to connect industrial devices and system and processes (such as smart sensors, tools, equipment, machines, and production workflows) to computing resources and expertise from domain experts and modeling experts. With advanced data analysis, processing, and simulation, IIoT can provide intelligent management for industrial devices and systems and processes to achieve a high level of efficiency, productivity, and performance.

For sophisticated devices or systems or processes, the simulation often involves building domain-specific models and/or device-specific simulation models and assigning them to the devices or processes in an IIOT environment. However, with increasing system and data complexities, domain experts and modeling experts can face challenges in developing the software that creates unique and replicable implementation models.

### SUMMARY

A platform is provided for implementing a digital representation of a particular industrial asset. The platform is configured to:
i) create an avatar corresponding to the particular industrial asset from at least one model and an avatar template maintained by the platform, wherein the avatar template refers to or incorporates the at least one model or part thereof, and the avatar is created from the avatar template and refers to or incorporates the avatar template or part thereof;
ii) execute a simulation that refers to or incorporates the avatar or part thereof, wherein execution of the simulation uses the at least one model of the avatar template referenced or incorporated by the avatar along with operational data corresponding to the particular industrial asset to generate a digital representation of the particular industrial asset that is customized for the particular industrial asset due to changes in characteristics of the particular industrial asset over time; and
iii) maintain the avatar over time.

In embodiments, the maintenance of the avatar in iii) can involve monitoring quality of the digital representation of the industrial asset generated by the simulation.

In embodiments, the execution of the simulation of ii) can employ a data workflow that collects and processes operational data corresponding to the particular industrial asset, and the maintenance of the avatar in iii) can involve monitoring data connections and data processing operations of the data workflow.

In embodiments, the maintenance of the avatar in iii) can involve model version control that tracks versions of a model developed over time. The model version control can be further configured to update one or more avatar templates, one or more avatars, or one or more simulations that reference or incorporate a given model or model version and provide for model version roll back, if required.

In embodiments, the platform can provide a user interface for uploading the at least one model into the platform from another system (e.g., a model development system).

In embodiments, the platform can provide a user interface for defining the avatar template involving user selection of the at least one model referred to or incorporated by the avatar template.

In embodiments, the platform can provide a user interface for defining the avatar involving user selection of the avatar template referred to or incorporated by the avatar.

In embodiments, the platform can provide a user interface for managing execution of the simulation.

In embodiments, the platform can implement a data workflow referenced or incorporated by the simulation, wherein the data workflow involves collection and processing of operational data corresponding to the particular industrial asset for use in the execution of the simulation.

In embodiments, the operational data collected by the data workflow can include real-time streaming data, episodic data, static data, or manually generated data.

In embodiments, the data workflow can be configured to collect operational data from a plurality of data sources.

In embodiments, the data workflow can be configured to collect operational data from at least one data source as specified by data stored as part of the data workflow.

In embodiments, the data workflow can be configured to process operational data as specified by data stored as part of the data workflow.

In embodiments, the processing of operational data performed by the data workflow can involve at least one of data mapping, data conversion, data storage, data validation, routing of data for input to the simulation, and routing of simulation result data output from the simulation.

In embodiments, the platform can provide a user interface for defining the data workflow.

In embodiments, the platform can provide a user interface for selecting and configuring the data workflow as part of the avatar template for use in one or more simulations that refer to or incorporate the avatar template.

In embodiments, the platform can be configured to output result data of the simulation to at least one decision system connected to the platform to enable monitoring and control of the particular industrial asset.

In embodiments, the platform can be configured to provide a plurality of modeling frameworks to support execution of the at least one model. For example, the plurality of modeling frameworks can include one or more Finite Element Analysis modeling frameworks, one or more Computational Fluid Dynamics modeling frameworks, one or more statistical modeling frameworks, one or more neural network modeling frameworks, or a combination thereof.

In embodiments, the platform can be configured to provide a user interface for testing the avatar template or avatar using simulated data.

This summary is provided to introduce a selection of concepts that are further described below in the detailed description. This summary is not intended to identify key or essential features of the claimed subject matter, nor is it intended to be used as an aid in limiting the scope of the claimed subject matter.

### BRIEF DESCRIPTION OF THE DRAWINGS

The subject disclosure is further described in the detailed description which follows, in reference to the noted plurality of drawings by way of non-limiting examples of the subject disclosure, in which like reference numerals represent similar parts throughout the several views of the drawings, and wherein:

FIG. 1 depicts a schematic diagram of a digital avatar system in accordance with an embodiment of the present disclosure;

FIG. 2 depicts a block diagram of another digital avatar system in accordance with an embodiment of the present disclosure;

FIG. 3 depicts a schematic diagram of a service architecture that may be used in the digital avatar platform of FIG. 2 in accordance with an embodiment of the present disclosure;

FIG. 4 depicts a diagram of functionality that can be embodied by the digital avatar platform of FIGS. 2 and 3 in accordance with an embodiment of the present disclosure;

FIG. 5 depicts a workflow diagram of functionality that can be embodied by the digital avatar platform of FIGS. 2 and 3 in accordance with an embodiment of the present disclosure;

FIG. 6 depicts a workflow diagram of functionality that can be embodied by the data ingestion service and the data workflow service of the digital avatar platform of FIG. 3 in accordance with an embodiment of the present disclosure;

FIG. 7 depicts a block diagram of functionality that can be embodied by the simulation management service of the digital avatar platform of FIG. 3 in accordance with an embodiment of the present disclosure;

FIG. 8 is a diagram of a logical data model for a model data object that can be used by the digital avatar platform of FIGS. 2 and 3 in accordance with an embodiment of the present disclosure;

FIG. 9 is a diagram of a computer processing system that can embody the digital avatar platform of FIGS. 2 and 3 in accordance with an embodiment of the present disclosure.

### DETAILED DESCRIPTION

The particulars shown herein are by way of example and for purposes of illustrative discussion of the embodiments of the subject disclosure only and are presented in the cause of providing what is believed to be the most useful and readily understood description of the principles and conceptual aspects of the subject disclosure. In this regard, no attempt is made to show structural details in more detail than is necessary for the fundamental understanding of the subject disclosure, the description taken with the drawings making apparent to those skilled in the art how the several forms of the subject disclosure may be embodied in practice. Furthermore, like reference numbers and designations in the various drawings indicate like elements.

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Certain examples commensurate in scope with the originally claimed subject matter are discussed below. These examples are not intended to limit the scope of the disclosure. Indeed, the present disclosure may encompass a variety of forms that may be similar to or different from the examples set forth below.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, unless expressly stated otherwise, the term “or” is intended to be inclusive (e.g., logical OR) and not exclusive (e.g., logical XOR). In other words, the phrase A “or” B is intended to mean A, B, or both A and B.

The Industrial Internet of Thing (IIoT) has become pervasive in many industries, particularly in large sectors, such as equipment manufacturing and energy production where large numbers of devices and processes are used over long periods of time and rely on intelligent management. The IIoT is a system of computing devices, digital sensing devices, intelligent equipment, or any type of smart objects that are provided with unique identifiers and the ability to transfer data over a network without human-to-human or human-to-computer interaction. IIOT devices are increasingly becoming ubiquitous and accessible. With a greater flow of information and incorporated data processing and/or simulation capabilities, an IIoT system may be used to provide users with the ability to track, monitor, and lighten workloads with automation and improved efficiency and better decision making.

The incorporation of an IIOT system as part of a business organization relies on one or more domain experts or modeling experts to adequately create one or more digitalized models that represent key processes, workflows, and physical devices, and implement such model(s) in an IIOT environment. The domain expert(s) or modeling expert(s) may be familiar with concepts of the models but may not be proficient in software development that is used to build model infrastructures. With increasing system and data complexities, a platform may be deployed that enables the domain experts and modeling experts to have a user-friendly software platform that supports creating unique and replicable models that may be used within the entire organization. The platform may be developed by software developers with the guidance of the domain experts and modeling experts to provide a bifurcation of expertise. Therefore, the extensive programing works, such as those related to model infrastructure, data complexity, parallel computing, network communication, etc., may be handled by software developers.

With the division of roles, the software developers may focus on model interfaces, database structures, processing and simulation algorithms, parallel computing, and the like. The domain experts and modeling experts may focus on the principle of the model, input and output of the model, modeling parameters, and their relations to the physical devices or processes that the model is assigned to rather than programming works. In other words, the software developers are responsible for providing a platform with a user-friendly interface that allows the users to create replicable implementation models with minimum programming effort while the domain experts and modeling experts may be responsible for providing guidance to model building, creating models using the platform provided, customizing the created models to fit the physical devices or processes, and implementing the models in the IIOT environment.

As described in this disclosure, a digital avatar is a digital representation of a physical device, a process, or a workflow. The physical device may be a physical object such as a sensor, a tool, equipment, a machine, and the like. The process may be a procedure involved in mechanical, physical, electrical, or chemical steps in manufacturing or other industrial operations. The workflow may be a sequence of industrial, administrative, or other processes. The digital avatar may comprise a dynamic simulation model specifically linked to the physical device, process, and/or workflow. The simulation model can be executed using operational data and/or device data corresponding to the physical device, process, and/or workflow as input. Result data generated by the execution of the simulation model can represent operational parameters or operational characteristics of the physical device, process, and/or workflow. Such result data can be output to a decision system (such as a business operational system) that uses the result data for modeling, monitoring, and/or optimizing parameter(s) and/or operation(s) of the physical device, process, and/or workflow. In this manner, the dynamic simulation model can provide an abstraction layer for applications and users to monitor and control physical devices, processes, or workflows in a robust manner. In addition, by linking together multiple digital avatars that represent similar devices, processes, or workflows, value-added data and/or learning results can be shared across the organization to improve the operational performance and reduce errors when using the similar devices, processes, or workflows.

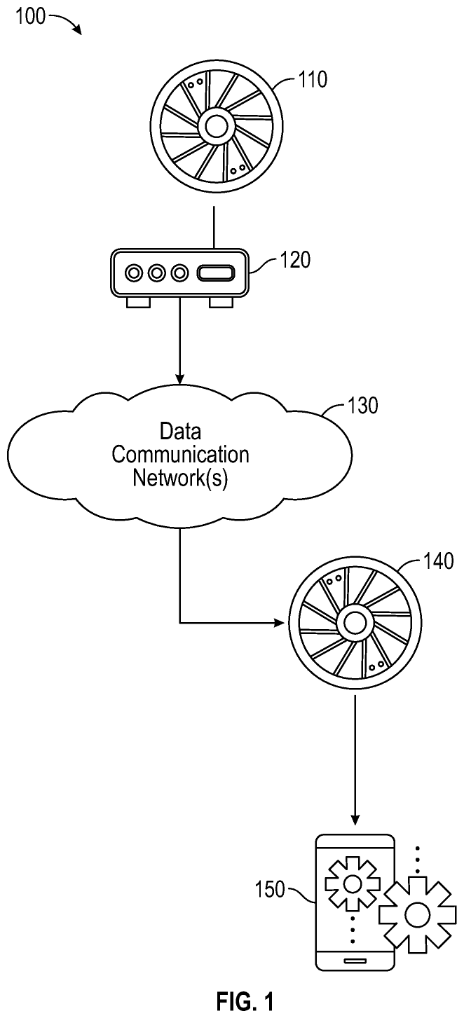

Turning now to the figures, FIG. 1 illustrates a digital avatar system 100 which includes a unique industrial asset 110. The asset 110 may be a physical device, a process, or a workflow used at an industrial facility or site. The system 100 also includes a unique digital avatar 140 corresponding to the asset 110. The digital avatar 140 functions as a digital representation of the asset 110. The digital avatar 140 includes a dynamic simulation model specifically linked to the asset 110. The simulation model can be executed using operational data corresponding to the asset 110 as input. Result data generated by the execution of the simulation model can represent operational parameters or operational characteristics of the asset 110. Such result data can be output to a decision system 150 (such as a business operational system) that uses the result data for modeling, monitoring, and/or optimizing parameter(s) and/or operation(s) of the asset 110. In this manner, the digital avatar 140 can provide an abstraction layer for applications and users to monitor and control the asset 110 in a robust manner.

The operational data corresponding to the asset 110 can be acquired by the asset 110 (e.g., acquired by the physical device or generated from the process or workflow), or by an associated device or sensor associated with the asset 110, and communicated over one or more data communication networks 130 via an industrial internet of things (IIoT) platform 120 that provides support for the asset 110. The operational data may be communicated as a data flow or data stream, batch data, and/or one or more data files, all of which can be generated during the operation of the asset 110. The operational data can be stored in a database or data store (for example, a data store in a cloud-computing environment) for supply to the digital avatar 140. The operational data can be ingested and optionally adapted for storage into a database (not shown) and for supply as input to the execution of the simulation model linked to the asset 110 as provided by the digital avatar 140. The adaptation can involve data mapping and data conversion operations. For example, direct measurements using the asset 110 may be used to calculate and/or estimate secondary measurements derivable from the direct measurements. Additionally or alternatively, the operational data may be filtered and/or sorted and/or otherwise transformed.

Result data generated by the execution of the simulation model of the digital avatar 140 can represent operational parameters or operational characteristics of the asset 110. Such result data can be output to a decision system 150 (such as a business operational system) that uses the result data for modeling, monitoring, and/or optimizing parameter(s) and/or operation(s) of the asset 110. For example, the decision system 150 may be a manufacturing management system and the digital avatar 140 may access the initial information about the asset 110 (e.g., material properties, defects, serial number, and the like existing at time of manufacture for a physical device). In one or more embodiments, as the asset 110 is deployed, the digital avatar 140 may obtain access to additional information from a management system assigned to the asset 110.

The system 100 of FIG. 1 can readily be expanded to include a plurality of unique digital avatars that correspond to a number of different IIOT assets. In this manner, the unique digital avatars are connected to the different IIOT assets and can be used to generate simulation result data that represents operational parameters or operational characteristics of the different IIOT assets. The simulated result data can be output to one or more decision systems for modeling, monitoring, and/or optimizing parameter(s) and/or operation(s) of the different IIOT assets.

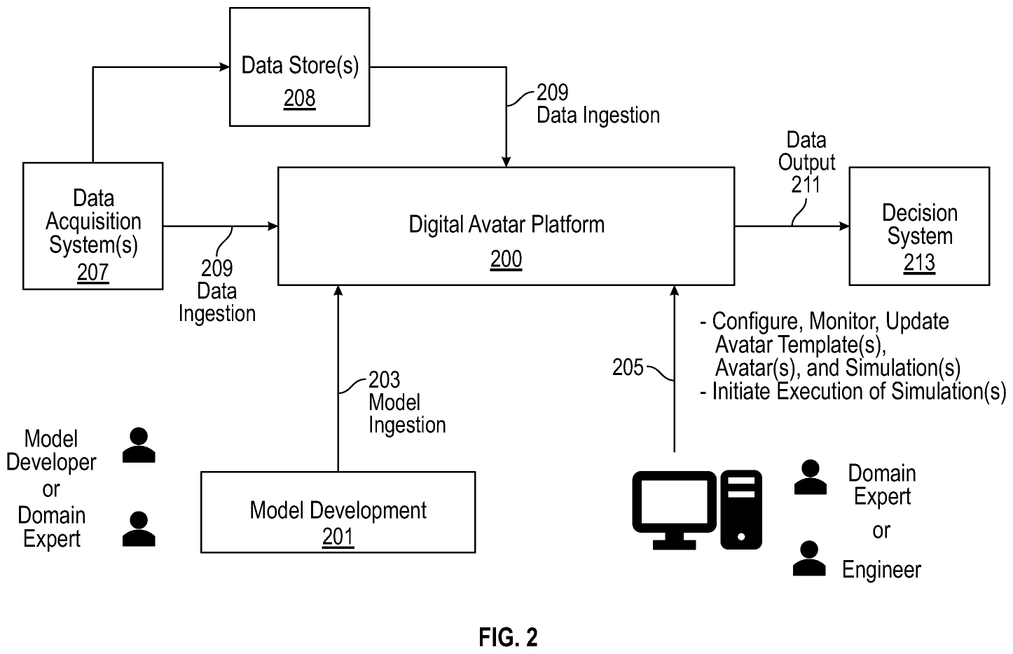

FIG. 2 illustrates a system which includes a digital avatar platform 200 that interfaces via a data communication network (not shown) to a data acquisition system 207 and to one or more data store(s) 208 for data ingestion 209. The data acquisition system 207 can include sensors or instrumentation that measure operational data corresponding to an industrial asset located at an industrial facility or site together with an industrial internet of thing (IIoT) platform that communicates the operational data to the digital avatar platform 200. The industrial asset as referred to herein can be a device or process or workflow. The operational data as referred to herein may be communicated as a data flow or data stream, batch data, and/or one or more data files, all of which can be generated during the operation of the industrial asset. The operational data as referred to herein can be real-time streaming data, episodic data, static data, or manually generated data. The operational data can also be stored in one or more data store(s) 208 (for example, a data store that is part of a cloud-computing environment) for communication to the digital avatar platform 200.

The digital avatar platform 200 includes software functionality that facilitates various aspects of the digital avatar implementation. Such aspects can include one or more of the following, for example, the software functionality (e.g., services) of the digital avatar platform 200 can provide for user interaction with users (e.g., model developer users and/or domain experts) to load one or more simulation models into the platform 200. The platform 200 can include data storage (or access to distributed data storage) that stores and maintains the model(s) loaded into the platform 200. A simulation model (or model data object) is computer software (e.g., program instructions and data) embodying a computational model that can be configured to emulate an industrial asset. The computational model can belong to one of a number of well-known model types, such as a Finite Element model, Computational Fluid Dynamics model, statistical model, and/or a neural network model. The computational model can be configured in a suitable modeling framework, which can employ one or more programming languages (such as C, C++, Fortran, Java, MATLAB, and Python) to represent the computational model. The computation model is typically not designed to emulate a particular instance of an industrial asset; instead, it is typically designed to emulate a type or class or category of industrial assets and then configured or initialized with parameters and/or conditions that correspond to a particular and unique industrial asset. Once configured and initialized, the computational model can be executed or run to emulate the particular industrial asset. The simulation model(s) can be developed by a user (e.g., model developer users and/or domain experts) in a separate model development environment 201 (e.g., in an offline mode separate from the platform 200) and ingested or loaded into the platform by model ingestion 203. The simulation model(s) loaded into and maintained by the platform 200 can be containerized, for example using Docker™ or other container platforms. The user interaction can be performed via data communication between a user-operated device (such as a computer system, laptop, tablet, smartphone, or other device operated by a user) and the platform 200 over a data communication network, such as the Internet or other wide area network.

The software functionality (e.g., services) of the digital avatar platform 200 can also provide for user interaction with users (e.g., model developer users and/or domain experts) to create and configure one or more avatar templates managed by the platform 200. The platform 200 can include data storage (or access to distributed data storage) that stores and maintains the avatar template(s) managed by the platform 200. An avatar template (or avatar template data object) includes data that references or links to a predefined avatar type. The avatar type can correspond to one or more types or classes or category of industrial assets. This reference or link associates the avatar template with the predefined avatar type. The avatar template can also include data that references or links or incorporates one or more simulation models (or model data objects) or parts thereof that correspond to the avatar type of the avatar template. The one or more simulation models are used during execution of a simulation. The simulation is based on operational data that is collected by the platform 200. There can be different model types based on the technology used to build the model. For example, the different model types can be Python-type models, MATLAB-type models, functional mockup unit (FMU) type models, etc. There can be different simulation behaviors that use the simulation models. The simulations that run the simulation models can be executed on demand or periodically. The simulations can run the simulation models in parallel or in series. The simulations can simulate the operations or processes performed by the industrial assets. Such simulations can represent the current state of an industrial asset. The simulations can also simulate “what if” scenarios to provide multiple realizations to determine a best outcome. The avatar template can also include data that specifies options or behavior of the one or more simulation models associated with the avatar template. The avatar template can also include data that defines one or more data workflows managed by the platform 200. Such data workflow(s) process the operational data collected by the platform 200 for input to the one or more simulation models associated with the avatar template as part of the simulation managed by the platform 200. The data workflow(s) can also process result data of the simulation for output from the platform 200, for example to decision system(s) 213. The data workflow(s) can collect real-time operational data from one or more data sources, map data between the data model of the data source and the data model(s) of the model(s), convert data (such as unit conversion or precision conversion), validate data, store data, route data for simulation, and route simulation result data for output. The platform 200 can maintain a plurality of avatar templates to cover different types or classes or categories of industrial assets. The user interaction can be performed via data communication between a user-operated device (such as a computer system, laptop, tablet, smartphone, or other device operated by a user) and the platform 200 over a data communication network, such as the Internet or other wide area network.

The software functionality (e.g., services) of the digital avatar platform 200 can also provide for user interaction with users (e.g., model developer users and/or domain experts) to create, configure and test one or more avatars managed by the platform 200. An avatar (or avatar data object) can include data that refers to or incorporates one or more of the avatar templates managed by the platform 200. By referencing or incorporating the one or more of the avatar templates, the avatar inherits the data included in the one or more referenced or incorporated avatar templates as described above. The avatar is unique and corresponds to an individual industrial asset. In particular, no two industrial assets can share the same avatar even if they are the same type and originate from the same design. In this manner, the industrial asset will have a corresponding avatar that will capture its individual traits as observed throughout its lifecycle. In this manner, the avatar can be configured as an instance of a particular avatar template that corresponds to the individual industrial assert. Whether through inheritance via an avatar template or through independent configuration, the avatar can include data that references or links to or incorporates one or more simulation models managed by the platform 200 and associated with the avatar, data that references or links to or incorporates one or more data workflows managed by the platform 200 and associated with the avatar, and/or data that references or links to or incorporates one or more simulations managed by the platform 200 and associated with the avatar. In embodiments, if and when an avatar instance is created from a given avatar template, the data representing the data source(s), simulations model(s), simulation behavior(s), and data transformation(s) of the avatar template can be used to configure API calls that are made when the avatar instance runs. For example, such API calls can be configured to fetch operational data obtained from one or more data sources and/or create a simulation. The user interface can support testing the avatar (or avatar template) using simulation data. The platform 200 can maintain a plurality of avatars corresponding to a number of different IIOT assets. The user interaction can be performed via data communication between a user-operated device (such as a computer system, laptop, tablet, smartphone, or other device operated by a user) and the platform 200 over a data communication network, such as the Internet or other wide area network.

The software functionality (e.g., services) of the digital avatar platform 200 can also provide for user interaction with users (e.g., engineers) to create, configure, execute and control one or more simulations managed by the platform 200. The platform 200 can include data processing functionality (or access to distributed data processing functionality) that performs the simulations managed by the platform 200. A simulation includes computer software (program instructions and data) that executes (or runs) a particular avatar instance over time. As part of the simulation, the data workflow(s) associated with the particular avatar instance are configured to process operational data of the corresponding industrial asset collected by the platform 200 for input to the one or more models associated with the avatar. The one or more simulation models are configured to simulate operational parameters of the corresponding industrial asset based on the input data to create a digital representation of the corresponding industrial asset. In the simulation, the data workflow(s) associated with the particular avatar instance can also be configured to process and store the result data of the simulation for output from the platform 200, for example, to one or more decision systems 213. In this manner, the simulation managed by the platform 200 can combine the one or more simulation models and operational data to create a digital representation of the industrial asset. Through the connection to the operational data (e.g., real-time data sources), when the industrial asset is subjected to a change in its operating conditions, the simulation updates the simulation model(s) and data accordingly to keep an accurate representation of the current conditions of the industrial asset. Furthermore, the operational data can be collected throughout the operational lifecycle of the industrial asset to constantly update the simulation. Finally, the simulation can be configured to execute autonomously and update the simulation model(s) and data sets to represent the current state of the industrial asset and thus effectively represent the “as maintained” status of the industrial asset. In embodiments, the simulation model(s) and simulation data can be used to determine if the avatar and corresponding simulation waits for a request to run (on demand) or if the platform 200 automatically manages when the avatar and corresponding simulation runs (periodic). The platform 200 can also use model behavior data to determine if multiple simulation models are run in parallel or series. The platform 200 can also use model behavior data to determine which simulation models are used in which simulations. The platform 200 can maintain a plurality of simulations corresponding to a number of different IIOT assets. The decision system(s) 213 can process the result data of the simulations maintained by the platform 200 for modeling, monitoring, and/or optimizing parameter(s) and/or operation(s) of the different IIOT assets. The user interaction can be performed via data communication between a user-operated device (such as a computer system, laptop, tablet, smartphone, or other device operated by a user) and the platform 200 over a data communication network, such as the Internet or other wide area network.

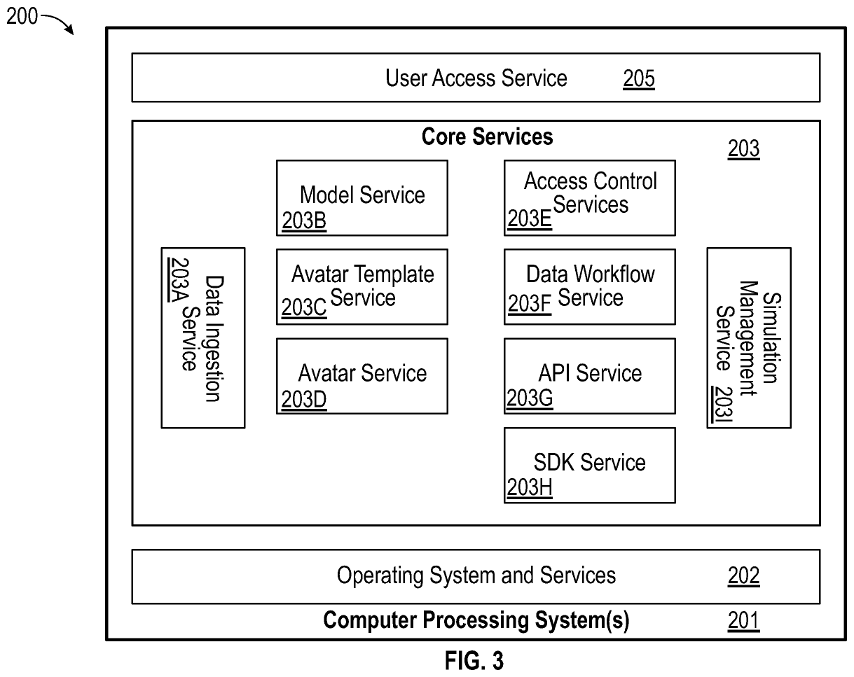

FIG. 3 illustrates a service architecture that may be used in the digital avatar platform of FIG. 2, which includes an operating system and services 202 that execute on one or more computer processing systems 201. The operating system and services 202 can manage persistent file and data storage in the memory of the computer processing system(s) 201 or manage persistent file and data storage in a data store that is part of a cloud-computing environment. The operating systems and services 202 can also manage compute functionality that execute on the computer processing system(s) 201 or in a cloud-computing environment. Examples of such compute functionality include compute engines and/or Kubernetes containerized applications that execute in the cloud computing environment. The operating system and services 202 can also provide for application lifecycle management for applications that execute on the computer processing system(s) 201 or in a cloud-computing environment. Examples of the application lifecycle management include the Elasticsearch, Logstach, and Kibana data processing functionality available from Elasticsearch B.V. of Amsterdam, The Netherlands. The operating systems and services 202 can also support and manage the collection of real-time data (e.g., data streaming). Examples of such data collection functionality include the open-source Kafka event streaming platform.

Core services 203 also execute on the one or more computer processing systems 201. The core services 203 can rely on and use the operating systems and services 202 as described herein. In embodiments, the core services 203 can include the following:
Data Ingestion Service 203A—this service coordinates and manages data collection from a number of data sources connected to the platform 200, such as real-time data streaming channels, batch data, files, databases and data stores, and cloud-based data sources.
Model Service 203B—this service coordinates and manages simulation models (or model data objects) implemented on the platform 200.
Avatar Template Service 203C—this service coordinates and manages avatar templates (or avatar template data objects) implemented on the platform 200.
Avatar Service 203D—this service coordinates and manages avatars/avatar instances (or avatar data objects) implemented on the platform 200.
Access Control Services 203E—this service implements role-based account controls for security related activities including user authentication and authorization.
Data Workflow Service 203F—this service coordinates and manages data workflow(s) implemented on the platform 200. Such data workflow(s) process the operational data collected by the platform 200 for input to the one or more simulation models as part of a simulation. The data workflow(s) can also process result data of the simulation for output from the platform 200. The data workflow(s) can collect real-time operational data from one or more data sources, map data between the data model of the data source and the data model(s) of the model(s), convert data (such as unit conversion or precision conversion), validate data, store data, route data for simulation, and route simulation result data for output. The data workflow(s) can be associated with simulation model(s), avatar template(s), avatar(s), avatar instance(s), and simulation(s) implemented on the platform 200.
API Service 203G—this service is configured to expose an aggregated application programming interface (API) to external users and systems to access the platform 200 programmatically.
SDK Service 203H—this service is configured to provide a software development kit (SDK) that facilitates the creation of applications or extensions or systems that interoperate with the functionality of the platform 200 as described herein. The SDK can take the form of APIs and libraries of reusable functions implemented by the platform 200. The SDK can also include sample software and/or technical notes and documentation. In embodiments, the SDK can be used to create a Docker container that contains one or more simulation models. The Docker container can establish communication channels and ports or other communication functionality necessary for the platform to communicate to the simulation model(s) contained by the Docker container. The Docker container can also establish the inputs, simulation commands, and outputs that are needed for execution of the simulation model(s) contained by the Docker container. The SDK can also support different types of simulation models (e.g., python-type simulation, fmu-type simulation, etc.)
Simulation Management Service 203I—this service coordinates the execution of simulations implemented on the platform 200, including storing and managing the execution and state of the simulations over time. The Simulation Management Service 203I can support simulations employing simulation models that belong to a number of well-known model types, such as Finite Element models, Computational Fluid Dynamics models, statistical models, and/or neural network models. The simulation models can be configured in a suitable modeling framework, which can employ one or more programming languages (such as C, C++, Fortran, Java, MATLAB, and Python) to represent the models. The Simulation Management Service 203I can maintain and execute the simulation model(s) as software containers. A software container is a standard unit of software that packages up code and all its dependencies (such as runtime environment, system tools, system libraries, and settings) so that the software runs quickly and reliably in the computing environment of the platform 200. The software container isolates software from its environment and ensures that it works uniformly and reliably in the computing environment. The software containers can be configured to communicate with one another through well-defined data channels. In one non-limiting example, the software containers can be implemented via Docker technology available from Docker, Inc. of Palo Alto, CA. The Simulation Management Service 203I can also be configured to monitor the performance and health of the simulation. This can involve monitoring the data connections and data processing operations of the data workflows implemented on the platform as well as monitoring the quality of the digital representation of the industrial asset as represented by the result data of the simulation to ensure that the digital representation of the industrial asset can be trusted for decision making. In embodiments, the Simulation Management Service 203I can perform one or more of the following checks:
success in getting input data from data sources;
monitoring simulation for timeout/crashes;
using a continuously changing variable (sine wave) as a “heartbeat” to ensure that a simulation is accessible; and
setting up monitoring variables unique to each model for health monitoring.

Furthermore, the platform 200 (e.g., Model Service 203B) can be configured to support model version control that tracks the versions of a simulation model developed over time. The model version control can also track the avatar template(s), avatar(s), and simulation(s) that reference or incorporate a given simulation model or model version and provide for model version roll back if required. In this manner, the model version control provides a mechanism to track which simulation model is associated with which historical data the avatar has produced for traceability, auditing, and troubleshooting.

User access services 205 also execute on the computer processing system(s) 201. The user access services 205 can rely on and use the core services 203 and/or the operating systems and services 202 as described herein. The user access services 205 can implement user interaction for user authentication and authorization and rely on and use the access control services 203E. The user access services 205 can also implement user interaction for creating, updating, managing, and maintaining the simulation models, avatar templates, avatars, avatar instances, and simulations implemented on the platform 200. For creating, updating, managing, and maintaining the simulation models, the user access services 205 can rely on and use the model service 203B. For creating, updating, managing, and maintaining the avatar templates, the user access services 205 can rely on and use the avatar template service 203C. For creating, updating, managing, and maintaining the avatars and avatar instances, the user access services 205 can rely on and use the avatar service 203D. For creating, updating, managing, and controlling the simulations, the user access services 205 can rely on and use the simulation management service 203I.

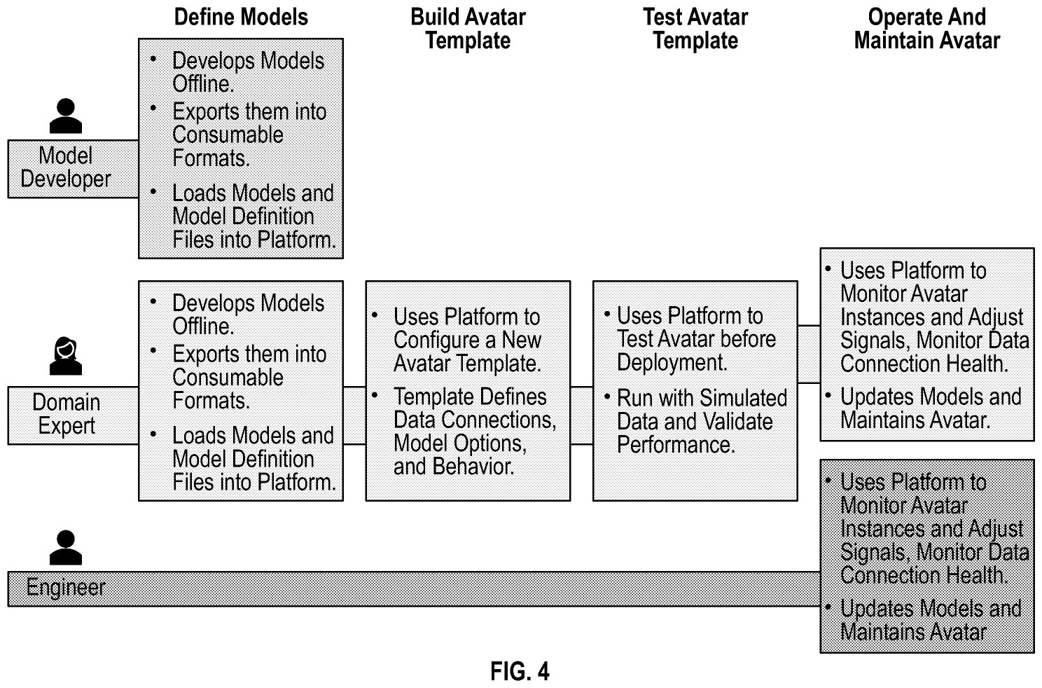

FIG. 4 illustrates user operations and interactions with the digital avatar platform 200 of FIGS. 2 and 3, including user operations and interactions by a model developer user, a domain user, and an engineer user.

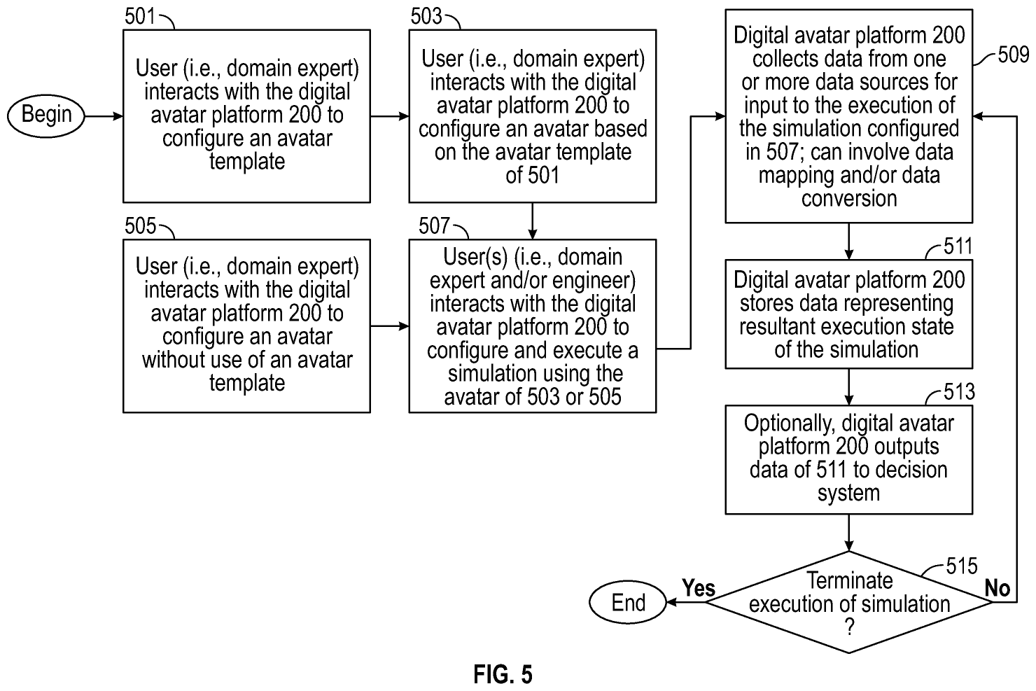

FIG. 5 illustrates user interactions with the digital avatar platform 200 of FIGS. 2 and 3. In block 501, a user (i.e., Domain Expert) can interact with the platform 200 to configure an avatar template as described herein. Such configuration can involve
defining or selecting an avatar template type for the avatar template. For example, an avatar template type can be selected from a list of avatar template types maintained by the platform 200 (e.g., avatar template service 203C);
selecting one or more simulation models linked to or incorporated into the avatar template. For example, one or more simulation models can be selected from a list of simulation models maintained by the platform (e.g., the model service 203B);
defining or selecting behaviors and attributes of the model(s) linked to or incorporated into the avatar template;
defining or selecting data workflow(s) linked to or incorporated into the avatar template. For example, one or more data workflows can be selected from a list of data workflows maintained by the platform 200 (e.g., data workflow service 203F). The user interaction can also specify parameters or other data that is stored as part of the data workflow(s) and that controls the data processing operations performed in such data workflow(s) (e.g., data mapping, data conversion, data validation, data storage, and data routing); and
configuring simulation model execution; such configuration can involve configuring execution of one or more simulation models on a periodic or on-demand basis. If there are multiple simulation models, such configuration can involve coordination of their execution. For example, arranging for serial execution of the multiple simulation models (for example, where the completion of execution of one simulation model triggers another simulation model to execute), parallel execution of the multiple simulation models, or possibly some combination of series and parallel execution.

In block 503, a user (i.e., Domain Expert) can interact with the platform 200 to configure an avatar or avatar instance based on the avatar template of 501. Such configuration can involve defining or selecting an avatar template for the avatar. For example, an avatar template can be selected from a list of avatar templates maintained by the platform 200 (e.g., avatar template service 203C). With the selection of the avatar template, the avatar can be constructed by referencing or incorporating the data of the selected avatar template or part thereof. In this manner, the avatar can be configured as an instance of a particular avatar template that corresponds to the individual industrial asset. In embodiments, a version or instance can be specified for the avatar, which allows avatar instances to be customized and have unique differences from the underlying template. Furthermore, an external identifier can be specified for the avatar, which can refer to the industrial asset represented by the avatar. The external identifier can be used to refer to the industrial asset outside the platform. For example, the external identifier can be a part number and serial number of the industrial asset. There can be more than one external identifier associated with the avatar.

In block 505, a user (i.e., Domain Expert) can interact with the platform 200 to configure an avatar or avatar instance without the use of an avatar template. In this case, such configuration can involve:
selecting one or more simulation models linked to or incorporated into the avatar. For example, one or more simulation models can be selected from a list of simulation models maintained by the platform (e.g., the model service 203B);
defining or selecting behaviors and attributes of the simulation model(s) linked to or incorporated into the avatar;
defining or selecting data workflow(s) linked to or incorporated into the avatar. For example, one or more data workflows can be selected from a list of data workflows maintained by the platform 200 (e.g., data workflow service 203F). The user interaction can also specify parameters or other data that is stored as part of the data workflow(s) and that controls the data processing operations performed in such data workflow(s) (e.g., data mapping, data conversion, data validation, data storage, and data routing); and
configuring simulation model execution. Such configuration can involve configuring execution of one or more simulation models on a periodic or on-demand basis. If there are multiple simulation models, such configuration can involve coordination of their execution. For example, arranging for serial execution of the multiple simulation models (for example, where the completion of execution of one simulation model triggers another simulation model to execute), parallel execution of the multiple simulation models, or possibly some combination of series and parallel execution.

Whether the avatar or avatar instance is configured through inheritance via an avatar template (block 503) or through independent configuration (block 505), the avatar or avatar instance can include data that references or links to or incorporates one or more simulation models managed by the platform 200 and associated with the avatar or avatar instance, and data that references or links to or incorporates one or more data workflows managed by the platform 200 and associated with the avatar or avatar instance.

In block 507, one or more user(s) (i.e., Domain Expert and/or Engineer) can interact with the platform 200 to configure and execute a simulation using the avatar or avatar instance of 503 or 505. Such configuration can involve defining or selecting an avatar or avatar instance for the simulation. For example, an avatar or avatar instance can be selected from a list of avatars maintained by the platform 200 (e.g., avatar service 203D). The simulations can simulate the operations or processes performed by the industrial assets. Such simulations can represent the current state of an industrial asset. The simulations can also simulate “what if” scenarios to provide multiple realizations to determine a best outcome. The “what if” scenarios can be used to look at multiple outcomes of a choice. For example, the simulations may calculate the current flowrate given the current position of a valve. The “what if” scenarios can be used to examine what the flowrate will be if the valve is opened 10% or 20% more.

In block 509, the platform 200 collects and processes data (i.e., operational data acquired from operation of the corresponding industrial asset) from one or more data sources for input to the execution of the simulation configured in 507. The collection and processing of the data can be controlled according to one or more data workflows managed by the platform 200 and associated with one or more simulations. The data workflow(s) can transform the data for input to the associated simulations. Such data transformation permits the operational data from one data source to be split and forwarded to multiple models or simulations. Such data transformation can also permit operational data from multiple data sources to be combined and forwarded to one simulation for execution. Also, minor arithmetic operations and formatting operations can be performed on the data in the process.

In block 511, the platform 200 stores data representing resultant execution state of the simulation.

In optional block 513, the platform 200 outputs the simulation result data of 511 to one or more decision systems connected to the platform 200. The decision system(s) can process the simulation result data for modeling, monitoring, and/or optimizing parameter(s) and/or operation(s) of the corresponding physical device or system or process or workflow.

In block 515, the platform 200 checks whether to terminate execution of simulation. Such termination can be dictated by user input, the expiration of a time period or timer associated with the simulation, or other conditions. If and when the simulation is terminated, the operations of the simulation end; otherwise (when the simulation is not terminated), the platform 200 repeats the operations of blocks 509 to 515.

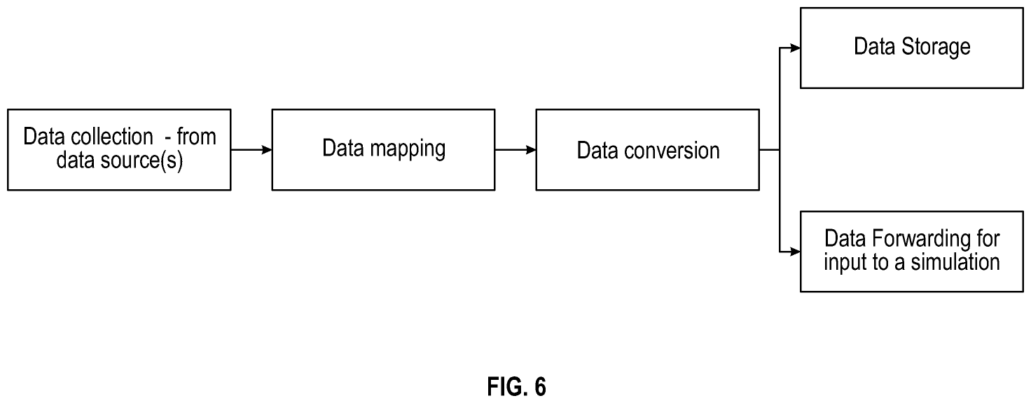

FIG. 6 illustrates operations carried out by the data ingestion services 203A and data workflow services 203F of the digital avatar platform of FIGS. 2 and 3. The data ingestion services 203A manage and perform data collection from one or more data sources. The data workflow services 203F can manage and perform data mapping, data conversion, data validation, data storage, data forwarding or routing for input to a simulation, and data forwarding or routing for output of simulation results.

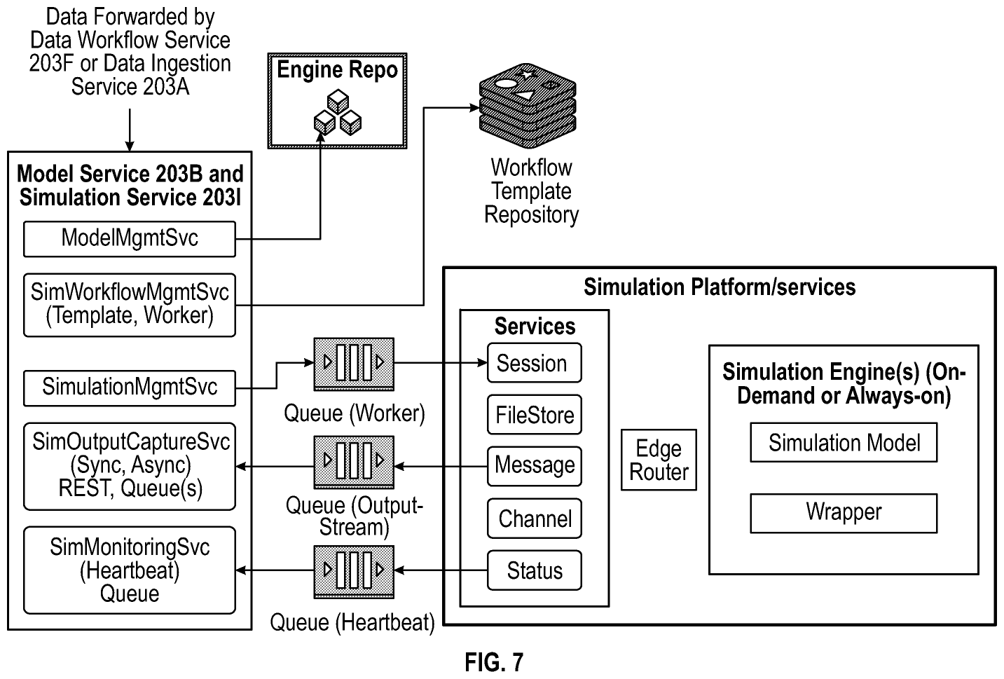

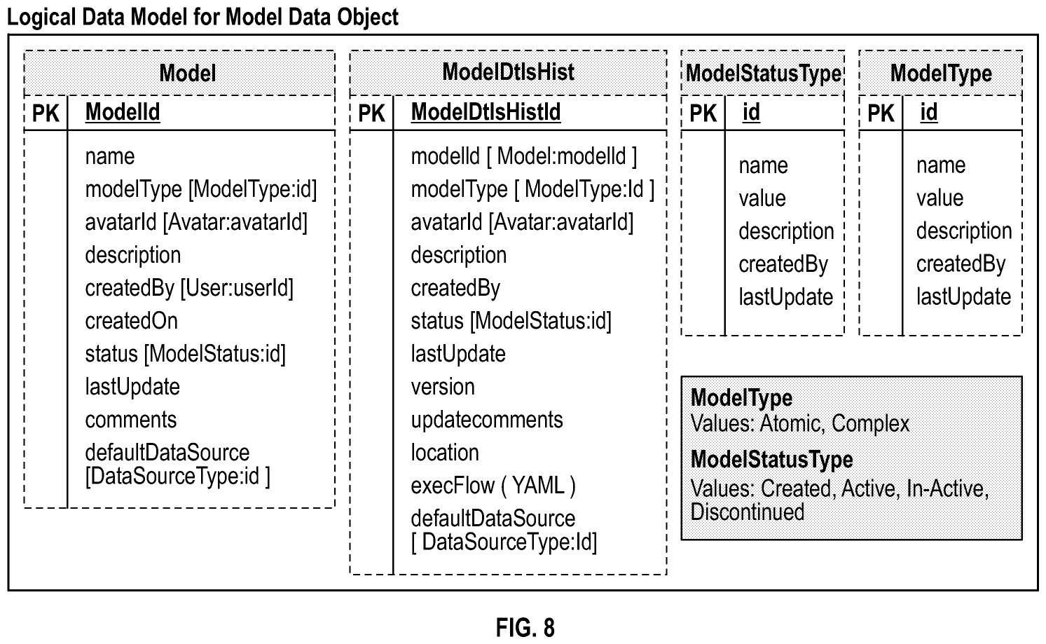

FIG. 7 illustrates software functionality (or modules) that can be embodied by the model service 203B and simulation management services 2031 of the digital avatar platform 200 of FIGS. 2 and 3. In this embodiment, software functionality (labeled “ModelMgmtSvc”) interfaces to a datastore or repository of simulation models maintained by the platform 200. When an avatar instance and associated simulation begins or resumes execution, this software functionality configures the simulation platform/services to run the associated simulation model(s) as part of one or more simulation engine(s) with a current state (or an initial state) as stored by the datastore. The software functionality (labeled “SimWorkflowManagementSvc”) interfaces to datastore or repository of workflow templates managed by the platform 200. This software functionality uses one or more workflow templates stored in the datastore and associated with an avatar instance/simulation to configure the simulation services used by the avatar instance/simulation. In embodiments, the simulation services can perform a number of tasks, including
loading data from one or more data objects associated with the avatar instance/simulation (e.g., such as data from an avatar data object; data from an avatar template data object; data from a model object, for example as shown in FIG. 8; and data from a simulation object;
configuring execution of one or more simulation models as part of a simulation performed by the simulation engine(s) of the simulation platform/services;
configuring and initiating data collection and/or data transformation and/or data validation performed by the data ingestion service 203A or data workflow service 203F for supply of operational data to the simulation engine(s) of the simulation platform/services as part of the simulation;
storing the operational data for input to the simulation engine(s) as part of the simulation;
initiating or running of the simulation performed by the simulation engine(s) using the operational data as input; and
storing and outputting (or publishing) result data generated by the simulation, for example to Decision System 213.

In embodiments, the simulation services can include software functionality (labeled “SimulationMgmtSvc”) that receives data forwarded by the data workflow service 203F (or data from the data ingestion service 203A) and stores the received data in a queue (labeled “worker”). The “worker” queue can be configured to output the data to the simulation platform/services for input to the appropriate simulation engine(s) that run the simulation model(s) for the avatar instance/simulation. The simulation services can also include software functionality (labeled “SimOutputCaptureSvc”) that receives result data generated by the simulation engine(s) of the simulation platform/services from the execution of the simulation model(s) for the avatar instance/simulation and stores the received result data in a queue (labeled “output-stream”). The “output-stream” queue can be configured to store the result data and/or output the result data to a decision system 213 as described herein. The simulation services can also include software functionality (labeled “SimMonitoringSvc”) that receives status data generated by the simulation platform/services that reflects the execution of the simulation model(s) for the avatar instance/simulation and stores the received status data in a queue (labeled “heartbeat). The platform 200 can process and analyze the status data stored in the “heartbeat” queue in order to monitor the status of the execution of the simulation model(s) for the avatar instance/simulation and make automated decisions and generate alerts when execution terminates unexpectantly. The simulation platform/services can include software functionality that manages services such as communication sessions, a file system for file storage, messaging, communication channels, and monitoring of simulation engine status. The simulation platform/services can also include an edge router that routes data to and from the simulation engine(s) that execute the simulation model(s) for the avatar instance/simulation. In embodiments, the simulation engines can be embodied by software containers (e.g., Docker containers) that include a wrapper and software functionality that implements a simulation model as shown.

FIG. 8 illustrates a logical data model for a simulation model (or model data object) implemented on the platform 200, which includes data fields that identify the simulation model (e.g., a model identifier labeled “modelId”, a model name labeled “name”, a model description labeled “description”, and a model type labeled “modelType” that refers to one of a number of predefined simulation model types, such as Atomic and Complex as shown), data fields that identify who created the simulation model and when created and updated (e.g., an identifier for a user who created the simulation model labeled “createdBy”, a timestamp for the date the simulation model was created labeled “createdOn”, and a timestamp for the date the simulation model was last updated labeled “lastUpdate”), a data field that identifies status of the simulation model (e.g., Created, Active, In-active, or Discontinued as provided by the data labeled “ModelStatusType”), a data field that identifies a default data source for the simulation model labeled “defaultDataSource”, and data fields that represent the history of any changes or updates to the simulation model over time labeled “ModelDtlsHist”.

In an embodiment, a logical data model for an avatar template (or avatar template data object) may be implemented on the platform 200, which includes the following:
AvatarType data fields that describe a type or class or group of avatars (e.g., an identifier or ID field, name field, description field, domain field, latest version identifier field, an identifier for a user who created the AvatarType data fields labeled “createdBy”, a timestamp for the date the AvatarType data fields was created labeled “createdOn”, an identifier for a user who last updated the AvatarType data fields labeled “updatedBy”, and a timestamp for the date the AvatarType data fields were last updated labeled “updatedOn”);
AvatarType Version data fields that are linked to the AvatarType data fields and describe a version of the type or class or group of avatars described by the linked AvatarType data fields (e.g., an identifier or ID field, name field, description field, status field, an identifier for a user who created the AvatarType Version data fields labeled “createdBy”, a timestamp for the date the AvatarTypeVersion data fields was created labeled “createdOn”, an identifier for a user who last updated the AvatarTypeVersion data fields labeled “updatedBy”, and a timestamp for the date the AvatarTypeVersion data fields was last updated labeled “updatedOn”); the AvatarTypeVersion data fields can also include data fields that link to one or more models; and

The avatar template data object can also link to or include Model data fields that describe a simulation model used in one or more simulations (e.g., an identifier or ID field, name field, description field, an identifier for a user who created the Model data fields labeled “createdBy”, a timestamp for the date the Model data fields was created labeled “createdOn”, an identifier for a user who last updated the Model data fields labeled “updatedBy”, and a timestamp for the date the Model data fields was last updated labeled “updatedOn”); the Model data fields can also include one or more data fields that specify parameters of the simulation model, one or more data fields that specify data inputs for the simulation model, and one or more data fields that specify result data outputs for the simulation model.

In an embodiment, a logical data model for an avatar (or avatar data object) implemented on the platform, includes the following:
Avatar data fields that describe an avatar (e.g., an avatar identifier labeled “Id”, an avatar name labeled “name”, an avatar description labeled “description”, an identifier for a user who created the Avatar data fields labeled “createdBy”, a timestamp for the date the Avatar data fields were created labeled “createdOn”, an identifier for a user who last updated the Avatar data fields labeled “updatedBy”, a timestamp for the date the Avatar data fields was last updated labeled “updatedOn”), a reference or link to an external data object for the industrial asset corresponding to the avatar, and a reference or link to one or more AvatarInstance data fields as described herein; the Avatar data fields can also refer to or link to AvatarType data fields that refers to one of a number of predefined avatar types (such as an ESP avatar type for an electric submersible pump, a PNX-Housing avatar type for a nuclear downhole tool and a Wet-Gas compressor avatar type);
AvatarInstance data fields that describe an instance of an avatar referenced thereto (e.g., (e.g., an avatar instance identifier labeled “Id”, an avatar instance name labeled “name”, an avatar instance description labeled “description”, an identifier for a user who created the AvatarInstance data fields labeled “createdBy”, a timestamp for the date the AvatarInstance data fields were created labeled “createdOn”, an identifier for a user who last updated the AvatarInstance data fields labeled “updatedBy”, a timestamp for the date the AvatarInstance data fields was last updated labeled “updatedOn”), and attributes of the avatar instance; the AvatarInstance data fields can also refer to or link to one or more Simulation data objects that describe simulations managed by the platform and run as part of the referenced avatar/avatar instance.

The avatar data object can be created by selecting or referencing an existing avatar template object. In this case, the data fields for the avatar data object can reference or incorporate one or more data fields of the existing avatar template object. The avatar can be defined first followed by an instance of the avatar. In this case, the avatar instance can be created by selecting or referencing an existing avatar, and the AvatarInstance data fields for the avatar instance can reference or incorporate one or more Avatar data fields of the existing avatar.

In an embodiment, a logical data model for a simulation (or simulation data object) can be implemented on the platform, which includes Simulation data fields that identify the simulation (e.g., simulation identifier labeled “Id”, a simulation name labeled “name”, a simulation description labeled “description”, an identifier for a user who created the Simulation data fields labeled “createdBy”, a timestamp for the date the Simulation data fields were created labeled “createdOn”, an identifier for a user who last updated the Simulation data fields labeled “updatedBy”, a timestamp for the date the Simulation data fields was last updated labeled “updatedOn”). The Simulation data fields can refer to or link to an avatar instance such that the simulation is associated with a unique avatar instance. The Simulation data fields can also refer to or link to a simulation-type data field labeled “simulationType” that refers to one of a number of predefined simulation types, such as “On-Demand” and “Always-ON”, simulation status data fields, SimulationRun data fields that track the execution behavior and associated status of the simulation, and ComputationalModelSimulationRun data fields that refer to or link to one or more simulation models and track the execution behavior and associated status of the simulation using the referenced simulation model.

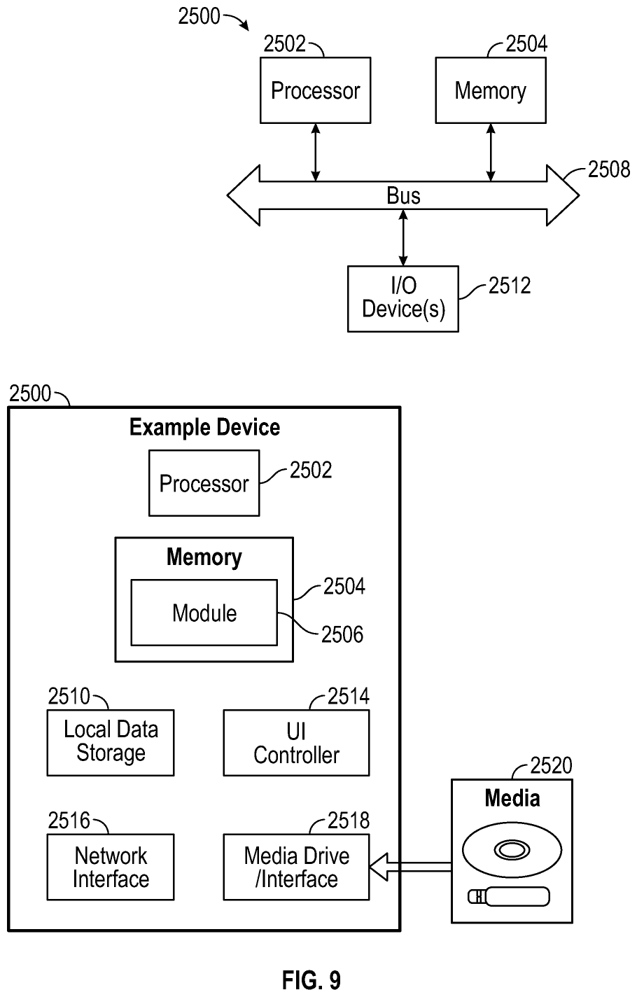

FIG. 9 illustrates an example device 2500, with a processor 2502 and memory 2504 that can be configured to implement various embodiments of the digital avatar platform as discussed in the present application. Memory 2504 can also host one or more databases and can include one or more forms of volatile data storage media such as random-access memory (RAM), and/or one or more forms of nonvolatile storage media (such as read-only memory (ROM), flash memory, and so forth).

Device 2500 is one example of a computing device or programmable device and is not intended to suggest any limitation as to scope of use or functionality of device 2500 and/or its possible architectures. For example, device 2500 can comprise one or more computing devices, programmable logic controllers (PLCs), etc.

Further, device 2500 should not be interpreted as having any dependency relating to one or a combination of components illustrated in device 2500. For example, device 2500 may include one or more of computers, such as a laptop computer, a desktop computer, a mainframe computer, etc., or any combination or accumulation thereof.

Device 2500 can also include a bus 2508 configured to allow various components and devices, such as processors 2502, memory 2504, and local data storage 2510, among other components, to communicate with each other.

Bus 2508 can include one or more of any of several types of bus structures, including a memory bus or memory controller, a peripheral bus, an accelerated graphics port, and a processor or local bus using any of a variety of bus architectures. Bus 2508 can also include wired and/or wireless buses.

Local data storage 2510 can include fixed media (e.g., RAM, ROM, a fixed hard drive, etc.) as well as removable media (e.g., a flash memory drive, a removable hard drive, optical disks, magnetic disks, and so forth). One or more input/output (I/O) device(s) 2512 may also communicate via a user interface (UI) controller 2514, which may connect with I/O device(s) 2512 either directly or through bus 2508.

In one possible implementation, a network interface 2516 may communicate outside of device 2500 via a connected network. A media drive/interface 2518 can accept removable tangible media 2520, such as flash drives, optical disks, removable hard drives, software products, etc. In one possible implementation, logic, computing instructions, and/or software programs comprising elements of module 2506 may reside on removable media 2520 readable by media drive/interface 2518.

In one possible embodiment, input/output device(s) 2512 can allow a user (such as a human annotator) to enter commands and information to device 2500, and also allow information to be presented to the user and/or other components or devices. Examples of input device(s) 2512 include, for example, sensors, a keyboard, a cursor control device (e.g., a mouse), a microphone, a scanner, and any other input devices known in the art. Examples of output devices include a display device (e.g., a monitor or projector), speakers, a printer, a network card, and so on.

Various systems and processes of present disclosure may be described herein in the general context of software or program modules, or the techniques and modules may be implemented in pure computing hardware. Software generally includes routines, programs, objects, components, data structures, and so forth that perform particular tasks or implement particular abstract data types. An implementation of these modules and techniques may be stored on or transmitted across some form of tangible computer-readable media. Computer-readable media can be any available data storage medium or media that is tangible and can be accessed by a computing device. Computer readable media may thus comprise computer storage media. “Computer storage media” designates tangible media, and includes volatile and non-volatile, removable, and non-removable tangible media implemented for storage of information such as computer readable instructions, data structures, program modules, or other data. Computer storage media include, but are not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other tangible medium which can be used to store the desired information, and which can be accessed by a computer.

Some of the methods and processes described above, can be performed by a processor. The term “processor” should not be construed to limit the embodiments disclosed herein to any particular device type or system. The processor may include a computer system. The computer system may also include a computer processor (e.g., a microprocessor, microcontroller, digital signal processor, general-purpose computer, special-purpose machine, virtual machine, software container, or appliance) for executing any of the methods and processes described above.

The computer system may further include a memory such as a semiconductor memory device (e.g., a RAM, ROM, PROM, EEPROM, or Flash-Programmable RAM), a magnetic memory device (e.g., a diskette or fixed disk), an optical memory device (e.g., a CD-ROM), a PC card (e.g., PCMCIA card), or other memory device.

Alternatively or additionally, the processor may include discrete electronic components coupled to a printed circuit board, integrated circuitry (e.g., Application Specific Integrated Circuits (ASIC)), and/or programmable logic devices (e.g., a Field Programmable Gate Arrays (FPGA)). Any of the methods and processes described above can be implemented using such logic devices.

Some of the methods and processes described above, can be implemented as computer program logic for use with the computer processor. The computer program logic may be embodied in various forms, including a source code form or a computer executable form. Source code may include a series of computer program instructions in a variety of programming languages (e.g., an object code, an assembly language, or a high-level language such as C, C++, or JAVA). Such computer instructions can be stored in a non-transitory computer readable medium (e.g., memory) and executed by the computer processor. The computer instructions may be distributed in any form as a removable storage medium with accompanying printed or electronic documentation (e.g., shrink wrapped software), preloaded with a computer system (e.g., on system ROM or fixed disk), or distributed from a server or electronic bulletin board over a communication system (e.g., the Internet or World Wide Web).

Although only a few example embodiments have been described in detail above, those skilled in the art will readily appreciate that many modifications are possible in the example embodiments without materially departing from this invention.

Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112, paragraph 6 for any limitations of any of the claims herein, except for those in which the claim expressly uses the words ‘means for’ together with an associated function.

What is claimed is:

1. A platform for implementing a digital representation of a particular industrial asset, the platform comprising:
at least one processor and memory storing instructions that, when executed by the at least one processor, are configured to
i) create an avatar corresponding to the particular industrial asset from at least one model and an avatar template maintained by the platform, wherein the avatar template refers to or incorporates the at least one model or part thereof, and the avatar is created from the avatar template and refers to or incorporates the avatar template or part thereof;
ii) execute a simulation that refers to or incorporates the avatar or part thereof, wherein execution of the simulation uses the at least one model of the avatar template referenced or incorporated by the avatar along with operational data corresponding to the particular industrial asset to generate a digital representation of the particular industrial asset that is customized for the particular industrial asset due to changes in characteristics of the particular industrial asset over time; and
iii) maintain the avatar over time.

2. A platform according to claim 1, wherein:
the maintenance of the avatar in iii) involves monitoring quality of the digital representation of the industrial asset generated by the simulation.

3. A platform according to claim 1, wherein:
the execution of the simulation of ii) employs a data workflow that collects and processes operational data corresponding to the particular industrial asset; and
the maintenance of the avatar in iii) involves monitoring data connections and data processing operations of the data workflow.

4. A platform according to claim 1, wherein:
the maintenance of the avatar in iii) involves model version control that tracks versions of a model developed over time.

5. A platform according to claim 1, wherein:
the model version control is further configured to update one or more avatar templates, one or more avatars, or one or more simulations that reference or incorporate a given model or model version and provide for model version roll back, if required.

6. A platform according to claim 1, wherein:
the instructions executing on the at least one processor are further configured to provide a user interface for uploading the at least one model into the platform from another system.

7. A platform according to claim 1, wherein:
the instructions executing on the at least one processor are further configured to provide a user interface for defining the avatar template involving user selection of the at least one model referred to or incorporated by the avatar template.

8. A platform according to claim 1, wherein:
the instructions executing on the at least one processor are further configured to provide a user interface for defining the avatar involving user selection of the avatar template referred to or incorporated by the avatar.

9. A platform according to claim 1, wherein:
the instructions executing on the at least one processor are further configured to provide a user interface for managing execution of the simulation.

10. A platform according to claim 1, wherein:
the instructions executing on the at least one processor are further configured to implement a data workflow that involves collection and processing of operational data corresponding to the particular industrial asset for use in the execution of the simulation.

11. A platform according to claim 10, wherein:
the operational data collected by the data workflow comprises real-time streaming data, episodic data, static data, or manually generated data.

12. A platform according to claim 10, wherein:
the data workflow is configured to collect operational data from a plurality of data sources.

13. A platform according to claim 10, wherein:
the data workflow collects operational data from at least one data source as specified by data stored as part of the data workflow.

14. A platform according to claim 10, wherein:
the data workflow processes operational data collected by the platform as specified by data stored as part of the data workflow.

15. A platform according to claim 10, wherein:
the processing of operational data performed by the data workflow involves at least one of data mapping, data conversion, data validation, data storage, routing of data for input to the simulation, and routing of simulation result data output from the simulation.

16. A platform according to claim 10, wherein:
the instructions executing on the at least one processor are further configured to provide a user interface for selecting and configuring the data workflow as part of the avatar template for use in one or more simulations that refer to or incorporate the avatar template.

17. A platform according to claim 1, wherein:
the instructions executing on the at least one processor are further configured to output result data of the simulation to at least one decision system connected to the platform to enable monitoring and control of the particular industrial asset.

18. A platform according to claim 1, wherein:
the instructions executing on the at least one processor are further configured to provide a plurality of modeling frameworks to support execution of the at least one model.

19. A platform according to claim 18, wherein:
the plurality of modeling frameworks comprise one or more Finite Element Analysis modeling frameworks, one or more Computational Fluid Dynamics modeling frameworks, one or more statistical modeling frameworks, one or more neural network modeling frameworks, or a combination thereof.

20. A platform according to claim 1, wherein:
the instructions executing on the at least one processor are further configured to provide a user interface for testing the avatar template or avatar using simulated data.
